(19) United States
(12) Patent Application Publication
(10) Pub. No.: US 2003/0027055 A1
(43) Pub. Date: Feb. 6, 2003

(54) Method and feedstock for making photomask material

(76) Inventors: Laura J. Ball, Fountaine le Port (FR); Sylvain Rakotoarison, Avon (FR)

Correspondence Address: CORNING INCORPORATED, SP-TI-3-1, CORNING, NY, 14831

(21) Appl. No.: 09/920,257

(22) Filed: Aug. 1, 2001

(51) Int. Cl. C03C 13/00; C03B 37/075; G02B 6/00; C03C 27/00; C03B 37/018; C03C 25/00; C03C 3/06; G03F 9/00; B32B 17/06; B32B 9/00

(52) U.S. Cl. 430/5; 65/391; 65/394; 65/397; 501/54; 428/428

(57) ABSTRACT

A method for manufacturing a photomask material includes delivering a powder containing silicon dioxide into a plasma to produce silica particles and depositing the silica particles on a deposition surface to form glass.

### CROSS-REFERENCE TO RELATED APPLICATIONS

This application relates to U.S. patent application Ser. No. ______, entitled “Method for Making Photomask Material by Plasma Induction,” filed ______, in the names of Laura Ball and Sylvia Rakotoarison.

### BACKGROUND OF INVENTION

1. Field of the Invention

The invention relates generally to methods for making fused silica. More specifically, the invention relates to a method for making a pure and water-free fused silica and use of the fused silica as photomask material.

2. Background Art

Photomasks are patterned substrates used in optical lithography processes for selectively exposing specific regions of a material to be patterned to radiation. FIG. 1A shows a photomask blank 1 which includes a substrate 3 made of high-purity quartz or glass. The most common type of glass used is soda line. Quartz is more expensive than soda line and is typically reserved for critical photomask applications. The substrate 3 is usually coated with a thin uniform layer of chrome or iron oxide 5. A chemical compound 7, known as “photo-resist,” is placed over the chrome or iron oxide layer 5. Although not shown, an anti-reflective coating may also be applied over the chrome or iron oxide layer 5 before applying the photo-resist 7. To form the photomask, a pattern is exposed onto the photo-resist 7 using techniques such as electron beam lithography. The pattern is then etched through the chrome or iron oxide layer 5. FIG. 1B shows a pattern etched in the chrome or iron oxide layer 5.

For production of integrated circuits, the finished photomask contains high-precision images of integrated circuits. The integrated circuit images are optically transferred onto semiconductor wafers using suitable exposure beams. The resolution of the projected image is limited by the wavelength of the exposure beam. Currently, advanced microlithography tools use 248-nm radiation (KrF) laser or 193-nm radiation (ArF) laser to print patterns with line width as small as 0.25 μm. New microlithography tools using 157-nm (F₂) radiation are actively under development.

One of the primary challenges of developing 157-nm microlithography tools is finding suitable photomask material. Calcium fluoride is the main candidate for lens material at 157-nm but cannot be used for photomask because it has a high coefficient of thermal expansion. Other fluoride crystal materials that have large band gaps and transmit at 157 nm are MgF₂ and LiF. However, MgF₂ has a high birefringence, and the manufacturing and polishing of LiF is unknown. Fused silica is used in 248-nm and 193-nm microlithography lenses. However, the fused silica produced by current processes is not adequate for use at 157-nm because its transmission drops substantially at wavelengths below 185 nm. The drop in transmission has been attributed to the presence of residual water, i.e., OH, H₂, and H₂O, in the glass, where the residual water is due to the hydrogen-rich atmosphere in which the glass is produced.

High-purity fused silica is commonly produced by the boule process. The boule process involves passing a silica precursor into a flame of a burner to produce silica soot. The soot is then directed downwardly into a refractory cup, where it is immediately consolidated into a dense, transparent, bulk glass, commonly called a boule. This boule can be used as lens and photomask material at appropriate wavelengths. Because of environmental concerns, the silica precursor is typically a hydrogen-containing organic compound, such as octamethyltetrasiloxane (OMCTS) or silane, and the conversion flame is typically produced by burning a hydrogen-containing fuel, such as CH₄. Halogen-based silica precursors, particularly SiCl₄, are other types of silica precursors that can be used in the process. Flame combustion of SiCl₄ using a hydrogen-containing fuel produces toxic and environmentally-unfriendly gases such as HCl.

U.S. patent application Ser. No. ______ by Laura Ball and Sylvia Rakotoarison, supra, discloses a process for making a water-free fused silica by plasma induction. The process involves injecting a silica precursor and oxygen into a plasma. The silica precursor is oxidized in the plasma to form silica particles which are deposited on a deposition surface. The deposition surface is heated to consolidation temperatures so that the silica particles immediately consolidate into glass. To make a water-free silica glass, a hydrogen-free silica precursor is used, and the process takes place in a controlled atmosphere that is substantially free of water vapor. One suitable hydrogen-free silica precursor for the process is SiCl₄. However, oxidation of SiCl₄ produces chlorine gas, as shown by equation (1) below:

SiCl₄(g)+O₂(g)→SiO₂(s)+Cl₂(g)

If chlorine is captured in the silica glass, the transmission for the 157-nm wavelength is decreased. In order to increase transmission of the silica glass at 157 nm, a chlorine-free precursor is desired.

### SUMMARY OF INVENTION

In one embodiment, the invention relates to a method of making fused silica which comprises generating a plasma, delivering a powder containing silicon dioxide into the plasma to produce silica particles, and depositing the silica particles on a deposition surface to form glass.

In another embodiment, the invention relates to a method for manufacturing a photomask material which comprises delivering a powder comprising silicon dioxide into a plasma to produce silica particles and depositing the silica particles on a deposition surface to form glass.

In another embodiment, the invention relates to a feedstock for making fused silica by plasma induction which comprises silica powder.

In another embodiment, the invention relates to a feedstock for making fused silica by plasma induction which comprises quartz.

In another embodiment, the invention relates to a photomask for use at 157-nm including a silica glass made by a method comprising generating a plasma, delivering a powder containing silicon dioxide into the plasma to produce silica particles, and depositing the silica particles on a deposition surface to form glass.

Other features and advantages of the invention will be apparent from the following description and the appended claims.

### BRIEF DESCRIPTION OF DRAWINGS

FIG. 1A is a cross-section of a photomask blank.

FIG. 1B is a cross-section of a photomask.

FIG. 2 illustrates a system for producing fused silica by plasma induction using a chlorine-free precursor.

### DETAILED DESCRIPTION

Embodiments of the invention provide a method for making silica glass by plasma induction using a chlorine-free precursor. In a preferred embodiment, the chlorine-free precursor is dry silica or quartz powder. There are several sources of silica powder that can be used. The silica powder may be obtained, for example, by sol-gel synthesis, such as disclosed in European Patent A-0271281. The nominal grain size of the powder can range from 0.1 to 300 μm. Natural or synthetic quartz can be used. Because the plasma induction process is itself a purifying process, the purity of the silica can be variable. The following is a description of specific embodiments of the invention.

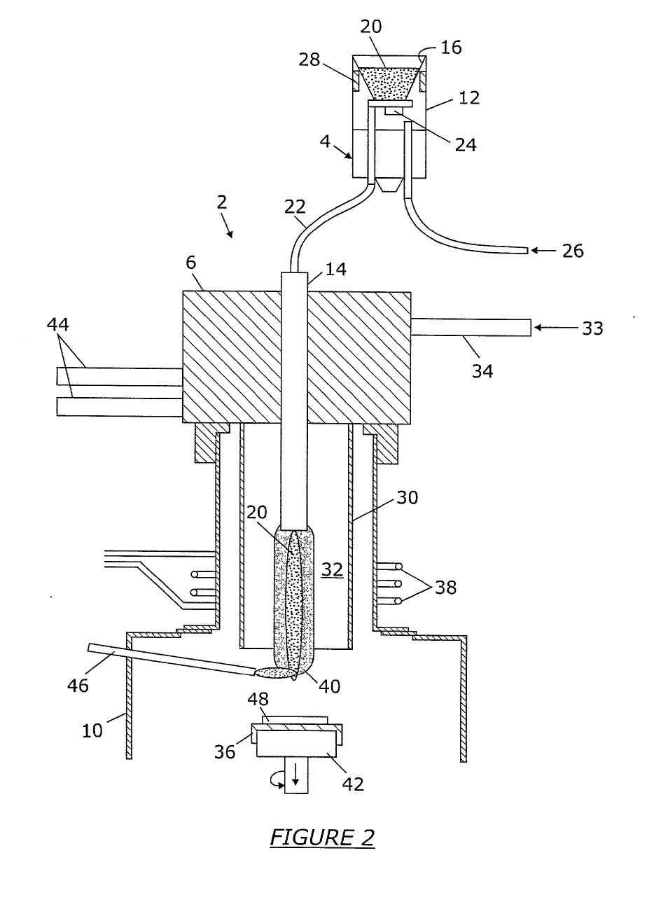

FIG. 2 illustrates a system, generally designated by numeral 2, for producing a chlorine-free silica glass by plasma induction. The system 2 comprises an induction plasma torch 6 mounted on a reactor 10, e.g., a water-cooled, stainless steel reactor, and an injection system 4 for injecting a silica precursor into the plasma torch 6. The injection system 4 includes a distributor 12 and an injector 14. The distributor 12 includes a container 16 which holds a dry chlorine-free silica (or quartz) powder 20. The container 16 is connected to the injector 14 via a feed line 22. The container 16 is mounted on a vibrator 24, which controls the rate at which the silica powder 20 is supplied to the injector 14. Gas flow 26 creates pressure in the distributor 12 which assists in transporting the powder 20 to the injector 14. A heating ring 28 is provided to heat the container 16 and maintain the powder 20 in a dry condition.

The plasma torch 6 includes a reaction tube 30 inside which a plasma production zone 32 is located. The reaction tube 30 may be made of high-purity silica or quartz glass to avoid contaminating the silica particles being made with impurities. The plasma production zone 32 receives plasma-generating gases 33 from a plasma-generating gas feed duct 34. Examples of plasma-generating gases 33 include argon, oxygen, air, and mixtures of these gases. The reaction tube 30 is surrounded by an induction coil 38, which generates the induction current necessary to sustain plasma generation in the plasma production zone 32. The induction coil 38 is connected to a high-frequency generator (not shown).

In operation, the plasma-generating gases 33 are introduced into the plasma production zone 32 from the feed duct 34. The induction coil 38 generates high-frequency alternating magnetic field within the plasma production zone 32 which ionizes the plasma-generating gases to produce a plasma 40. Water coolers 44 are used to cool the plasma torch 6 during the plasma generation.

The injector 14 projects the powder 20 into the plasma 40. The powder 20 is converted to fine silica particles in the plasma 40. The silica particles are directed downwardly and deposited on a substrate 36 on a rotating table 42. The substrate 36 is typically made of fused silica. In one embodiment, the plasma torch 6 heats the substrate 36 to consolidation temperatures, typically 1500 to 1800° F., so that the silica particles immediately consolidate into glass 48. In other embodiments, the silica particles deposited on the substrate 36 may be consolidated into glass in a separate step.

The rotating table 42 is located within the reactor 10, and the atmosphere in the reactor 10 is sealed from the surrounding atmosphere. The atmosphere in the reactor 10 is controlled such that it is substantially free of water, e.g., the water vapor content in the atmosphere is less than 1 ppm by volume. This can be achieved, for example, by purging the reactor 10 with a dry and inert gas and using a desiccant, such as zeolite, to absorb moisture.

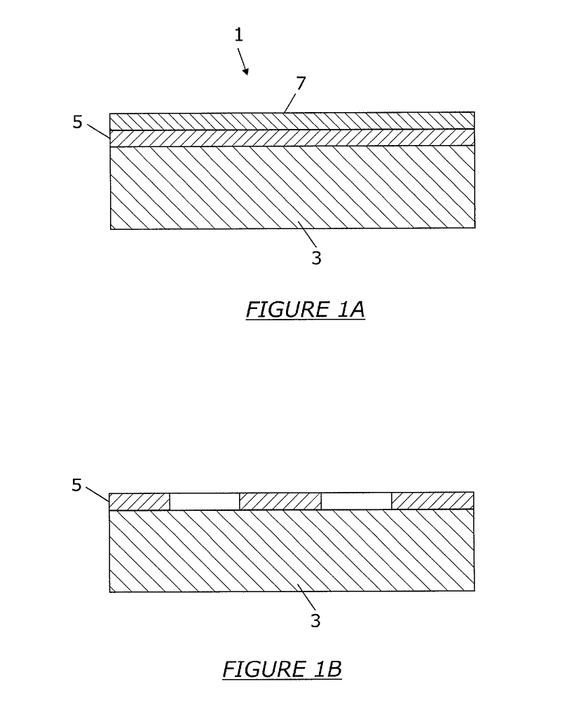

The glass 48 can be used as photomask material for microlithography applications or other applications requiring chlorine-free glass. In alternate embodiments, the silica glass may be doped with small amounts of other elements, such as F, B, Al, Ge, Sn, Ti, P, Se, Er, Na, K, Ca and S. In FIG. 1, a dopant feed 46 is inserted through the wall of the reactor 10. The dopant feed 46 can be used to supply the dopant materials toward or through the center of the plasma 40 at the same time that the injector 14 projects the powder 20 into the plasma 40. Examples of dopant materials include, but are not limited to, fluorinated gases and compounds capable of being converted to an oxide of B, Al, Ge, Sn, Ti, P, Se, Er, or S. Examples of fluorinated gases include, but are not limited to, CF₄, CF₆, chlorofluorocarbons, e.g., CFₓCl₄₋ₓ, where x ranges from 1 to 3, NF₃, SF₆, SiF₄, C₂F₆, and F₂. In an alternate embodiment, a fluorine-doped silica glass can be made by doping the powder 20 with fluorine prior to injecting the powder 20 into the plasma 40. This eliminates the use of toxic fluorinated gases in the plasma 40.

The invention provides several advantages. The chlorine-free silica glass produced by the method of the invention can be used as a photomask material for microlithography applications, particularly 157-nm microlithography applications. The chlorine-free silica glass produced by the method of the invention can also be used in other applications that are sensitive to chlorine-levels in the glass. Other applications that are not sensitive to chlorine-levels in the glass can also benefit from the invention. Using a chlorine-free silica precursor eliminates production of chlorine gas. Further, the silica glass can be produced in one step, i.e., deposition and consolidation into glass are done at the same time. For fluorine-doped glass, use of toxic fluorine gases during deposition can be eliminated by using silica precursor that already contains fluorine. The plasma induction process itself is a purification process. Therefore, the purity of the silica powder used as the silica precursor can be variable. Alternatively, natural or synthetic quartz can be used as the silica precursor.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. A method of making fused silica, comprising:
generating a plasma;
delivering a powder containing silicon dioxide into the plasma to produce silica particles; and
depositing the silica particles on a deposition surface to form glass.

2. The method of claim 1, wherein a nominal grain size of the powder ranges from 0.1 to 300 μm.

3. The method of claim 1, further comprising delivering a dopant material into the plasma to produce doped silica particles.

4. The method of claim 3, wherein the dopant material comprises a compound capable of being converted to an oxide of at least one member of the group consisting of B, Al, Ge, Sn, Ti, P, Se, Er, Na, K, Ca and S.

5. The method of claim 3, wherein the dopant material comprises a fluorine compound.

6. The method of claim 5, wherein the fluorine compound is selected from the group consisting of CF₄, CFₓCl₄₋ₓ, where x ranges from 1 to 3, NF₃, SF₆, SiF₄, C₂F₆, and F₂.

7. The method of claim 1, wherein the plasma is generated by induction with a high frequency generator.

8. The method of claim 1, wherein the powder further comprises a dopant material.

9. The method of claim 8, wherein the dopant material comprises fluorine.

10. The method of claim 1, wherein the silica is formed in an enclosure having a water vapor content less than 1 ppm by volume.

11. The method of claim 1, wherein the powder is silica.

12. The method of claim 1, wherein the powder is natural quartz.

13. The method of claim 1, wherein the powder is synthetic quartz.

14. A method for manufacturing a photomask material, comprising:
delivering a powder containing silicon dioxide into a plasma to produce silica particles; and
depositing the silica particles on a deposition surface to form glass.

15. A feedstock for making fused silica by plasma induction comprising silica powder.

16. The feedstock of claim 15, wherein a nominal grain size of the powder ranges from 0.1 to 300 μm.

17. The feedstock of claim 15, wherein the silicon-dioxide powder is doped with fluorine.

18. A feedstock for making fused silica by plasma induction comprising quartz.

19. A photomask for use at 157-nm including a silica glass made by a method comprising:
generating a plasma;
delivering a powder containing silicon dioxide into the plasma to produce silica particles; and
depositing the silica particles on a deposition surface to form glass.
